(19) United States
(12) Patent Application Publication
(10) Pub. No.: US 2022/0163897 A1
(43) Pub. Date: May 26, 2022

(54) OPTICAL ILLUMINATION SYSTEM FOR GUIDING EUV RADIATION

(71) Applicant: Carl Zeiss SMT GmbH, Oberkochen (DE)

(72) Inventor: Michael Patra, Oberkochen (DE)

(21) Appl. No.: 17/666,874

(22) Filed: Feb. 8, 2022

Related U.S. Application Data
(63) Continuation of application No. PCT/EP2020/069544, filed on Jul. 10, 2020.

(30) Foreign Application Priority Data
Aug. 9, 2019 (DE) 102019212017.2

(51) Int. Cl. G03F 7/20; G02B 27/42; G02B 5/08

(52) U.S. Cl. CPC G03F 7/70158; G03F 7/70033; G02B 5/0891; G03F 7/70575; G02B 27/425; G03F 7/702

(57) ABSTRACT

An optical illumination system guides EUV radiation between a source region of an EUV light source and an object field, in which an object to be imaged is arrangeable. The illumination system has at least two EUV mirror components which reflect the EUV radiation and sequentially guide the EUV radiation between the source region and the object field. An optical diffraction component for suppressing extraneous light radiation is arranged on each of the two EUV mirror components. The two optical diffraction components are designed to suppress different extraneous light wavelengths. A first of the two optical diffraction components, which is arranged on a first of the EUV mirror components, is a grating with at least one first structure depth. A second of the two optical diffraction components, which is arranged on a second of the EUV mirror components, is a grating with at least one second different structure depth. The result can be improved suppression of extraneous light.

### CROSS-REFERENCE TO RELATED APPLICATIONS

The present application is a continuation of, and claims benefit under 35 USC 120 to, international application PCT/EP2020/069544, filed Jul. 10, 2020, which claims benefit under 35 USC 119 of German Application No. 10 2019 212 017.2, filed Aug. 9, 2019. The contents of the following patent applications are incorporated herein by reference in their entirety: DE 10 2019 212 017.2, DE 10 2019 210 450.9 and PCT/EP 2020/050809.

### FIELD

The disclosure relates to an optical illumination system for guiding EUV radiation. The disclosure also relates to an optical system having such an illumination system and a projection optical unit, to an optical system having such an illumination system and an EUV light source, to a projection exposure apparatus having such an illumination system, to a method for producing a microstructured or nanostructured component element with such a projection exposure apparatus, and to a structured component element produced with such a production method.

### BACKGROUND

Optical systems for guiding EUV radiation are known from DE 10 2009 044 462 A1, DE 10 2011 082 065 A1, from DE 10 2017 217 867 A1, from US 2015/0049321 A1, and from US 2019/0033723 A1.

### SUMMARY

The present disclosure seeks to improve extraneous light suppression in an optical illumination system of the type mentioned in the introductory part.

The disclosure recognizes that, because the EUV used light is sequentially reflected between the source region and the object field by a plurality of EUV mirror components, diffraction components can be arranged on at least two of these EUV mirror components which are sequentially arranged in the beam path of the EUV used light to suppress different extraneous light wavelengths. The two optical diffraction components having the different structure depths are thus designed to suppress different extraneous light wavelengths. This can allow for effective suppression of two different extraneous light wavelengths without the need for a complex optical diffraction component on one of the EUV mirror components, which simultaneously suppresses both extraneous light wavelengths. This can reduce the outlay for extraneous light suppression. The extraneous light can have an infrared wavelength, for example in the range between 800 nm and 12 μm, such as in the range of 1 μm, or in the range between 10 μm and 11 μm. The various extraneous light wavelengths that are suppressed in each case by one of the two optical diffraction components can be the wavelength of a prepulse and the wavelength of a main pulse of an EUV plasma source. An EUV plasma source with prepulse and main pulse is known from WO 2013/107660 A2. The optical diffraction components arranged on the at least two EUV mirror components differ from one another. Each of the optical diffraction components on the two EUV mirror components has a different extraneous light target wavelength and can have exactly one different extraneous light target wavelength. Each of the optical diffraction components on the two EUV mirror components can also cover a range of extraneous light target wavelength ranges in the suppression, wherein the extraneous light target wavelength ranges of the optical diffraction components differ. Alternatively or additionally, each of the optical diffraction components can have a different main target wavelength for the extraneous light, but at the same time also suppress other secondary wavelengths. In addition to the two EUV mirror components equipped with the optical diffraction components, the optical system can also have further EUV mirror components in the EUV used light beam path between the source region and the object field. In this case, more than two of the EUV mirror components can also be equipped with optical diffraction components for suppressing at least two extraneous light wavelengths. Three or more different extraneous light wavelengths can then also be suppressed.

The suppression of different extraneous light wavelengths by the two diffraction gratings comes about due to the different structure depths of the two diffraction gratings arranged in each case on one of the two EUV mirror components. A difference between two diffraction structure levels, which complement each other in their effect in one of the diffraction gratings for extraneous light suppression through destructive interference, can be λ/4 or λ/6, wherein λ is the target wavelength to be suppressed or an effective target wavelength corrected by the angle of incidence of the extraneous light to be suppressed on the diffraction grating. The different structure depths of the two diffraction gratings can differ by at least a factor Δd/d=10%. Here, Δd is the difference between the structure depths of the two diffraction gratings, wherein the respective structure depth denotes the difference in height between at least two diffraction structure levels of the respective diffraction grating, which complement each other in their effect for suppressing extraneous light through destructive interference. d is the greater of the two structure depths here. This difference Δd/d can be greater than 20%, can be greater than 30%, and can also be greater than 50%. Corresponding differences then arise for the different extraneous light wavelengths λ1, λ2 to be suppressed, so that here, too, a difference between the extraneous light wavelengths to be suppressed, Δλ/λ1, can be greater than 10%, with λ1 being the greater of the two extraneous light wavelengths to be suppressed and Δλ=λ1−λ2 being the difference between these two extraneous light wavelengths.

In a variant of the optical illumination system, the two diffraction gratings, which are each arranged on one of the two EUV mirror components, can also have the same structure depths, but can nevertheless be embodied to suppress different extraneous light wavelengths. This can be the case when differences in the angles of incidence of the EUV radiation on these two diffraction gratings and also the differences between the different extraneous light wavelengths to be suppressed exactly balance each other out in the design of the structure depths on the two diffraction gratings.

The optical diffraction component can carry a coating that is highly reflective for the EUV radiation used for object illumination, for example a multilayer coating.

An embodiment of at least one of the diffraction gratings as a binary grating with two differing diffraction structure levels within a grating period and the same structure section lengths along a period extent direction can involve comparatively little outlay in terms of manufacturing.

A diffraction grating with at least three differing diffraction structure levels can make possible a very effective suppression of exactly one extraneous light target wavelength and/or a suppression of an extraneous light wavelength range and/or of a plurality of differing extraneous light wavelengths. Optical diffraction components in the form of diffraction gratings described in DE 10 2019 210 450.9 and PCT/EP 2020/050809 can be used. A structure depth or a structure level difference between the diffraction structure levels, which complement each other in their effect of suppressing extraneous light through destructive interference, can be λ/4 or λ/6. The diffraction grating can be divided into four structure sections within a respective grating period. The four structure sections can each have structure depths that differ from one another. Alternatively, a division within the grating period into four structure sections can be realized such that two of the four structure sections are embodied as neutral structure sections, one of the structure sections is embodied as a positive structure section, and one of the structure sections is embodied as a negative structure section. The four structure sections can have the same length along a period extent direction. The two neutral structure sections can also be combined into one structure section. In this regard, too, reference is made to the description in PCT/EP 2020/050809.

Such a diffraction grating with at least three differing diffraction structure levels can lead, when used on the EUV collector mirror, to an effective suppression of different pump light wavelengths, which can be used for plasma generation within a plasma EUV light source. Optionally, only one section of the collector mirror may be provided with such a diffraction grating, and any remaining reflective surface of the EUV collector mirror may have no optical diffraction component or alternatively be provided with a more simply designed diffraction component, for example with a binary grating.

Designs of the various possible EUV mirror components with a diffraction grating with two differing diffraction structure levels, for example with a binary grating, can make possible an effective suppression of an extraneous light target wavelength and of a wavelength range around this extraneous light target wavelength. The production of such a diffraction grating with exactly two differing diffraction structure levels is comparatively simple.

All optical diffraction components can be designed for example to suppress different extraneous light wavelengths.

The extraneous light suppression can help ensure that subsequent optical components of the illumination system or a downstream projection system are not undesirably thermally loaded with the extraneous light.

Design variants of the EUV mirror components, which are each embodied with the optical diffraction component, have proven to be suitable designs depending on the suppression boundary conditions that are directed at the extraneous light.

As an alternative to a pupil facet mirror, the optical illumination system can also have a specular reflector. A specular reflector is described, for example, in U.S. Pat. No. 8,934,085 B2, in US 2006/0132747 A1, in EP 1 614 008 B1 and in U.S. Pat. No. 6,573,978.

The optical illumination system can be designed such that radiation in an angle of incidence range between a minimum angle of incidence and a maximum angle of incidence is impingeable on at least one reflection section of one of the EUV mirror components within a beam path of the EUV radiation. One of the above-discussed optical diffraction components for suppressing extraneous light radiation also guided in the beam path can be arranged on the reflection section. The optical diffraction component can be embodied such that, in the entire angle of incidence range, the extraneous light radiation is suppressed with a suppression ratio between an intensity of the extraneous light incident on the reflection section and an intensity of the extraneous light emerging from the reflection section in the direction of the beam path that is better than 1000. This suppression ratio can be better than 10⁴, such as better than 10⁵. The optical system can have at least one facet mirror as an EUV mirror component, wherein the reflection section on which the optical diffraction component is arranged is part of the facet mirror. At least one field facet, at least one pupil facet, or at least one section of a respective facet can be used as such a reflection section which is part of the facet mirror. If one of the facets is implemented by a plurality of correspondingly grouped and interconnected individual mirrors, for example by MEMS individual mirrors, the reflection section can also be embodied on at least one and for example on a plurality of such individual mirrors.

The features of an optical system, of a projection exposure apparatus, of a production method or of a microstructured or nanostructured component correspond to those already discussed above with reference to the optical illumination system.

The component can be a semiconductor chip, such as a memory chip.

### BRIEF DESCRIPTION OF THE DRAWINGS

Exemplary embodiments of the disclosure will be explained in more detail below with reference to the drawings, in which:

FIG. 1 schematically shows a projection exposure apparatus for EUV microlithography;

FIG. 2 shows, likewise schematically and in a meridional section, an embodiment of an optical system of the projection exposure apparatus with an illumination optical unit shown in greater detail;

FIG. 3 shows a view of a facet arrangement of a field facet mirror of the illumination optical unit of the projection exposure apparatus in the “rectangular field” embodiment;

FIG. 4 shows, in an illustration similar to FIG. 3, a facet arrangement of a further embodiment of a field facet mirror in the “arc field” embodiment;

FIG. 5 shows an embodiment of a facet arrangement of a pupil facet mirror;

FIG. 6 shows a section through an embodiment of an optical grating for the diffractive, extraneous-light-suppressing effect, wherein a sectional plane is perpendicular to a longitudinal extent of diffraction structures of the optical grating;

FIG. 7 shows, in a meridional section, an optical path to and from a plasma source region of an EUV light source of the projection exposure apparatus according to FIG. 1, wherein a diffractive, extraneous-light-suppressing effect of an optical grating in the embodiment according to FIG. 6 on an EUV collector mirror is shown, which represents a first component guiding EUV used light downstream of the EUV source region;

FIG. 8 shows a further embodiment of an illumination optical unit with two facet mirrors and a downstream transmission optical unit with three mirrors;

FIG. 9 shows, in an illustration that is similar to FIG. 6, a section through a further embodiment of an optical grating as an optical diffraction component for the diffractive, extraneous-light-suppressing effect, embodied to suppress different extraneous light wavelengths;

FIG. 10 shows a plan view of a further embodiment of an optical grating for suppressing different extraneous light wavelengths with structure sections arranged in a grid-type manner in rows and columns, the structure depths of which are illustrated by an indication of corresponding depth values;

FIG. 11 shows the optical diffraction grating according to FIG. 10, wherein etching depth regions corresponding to the depth values of FIG. 10 are illustrated by different types of hatching;

FIG. 12 shows, in an illustration similar to FIG. 9, a further embodiment of an optical diffraction grating for suppressing extraneous light, different extraneous light wavelengths, embodied with three diffraction structure levels that differ from one another;

FIG. 13 shows a more abstracted meridional section than FIG. 7 for illustrating angles of incidence of different individual rays which, starting from the plasma source region of the EUV light source, are incident on the EUV collector for focusing on an intermediate focus of a beam path of the EUV radiation;

FIG. 14 shows, in an illustration similar to FIG. 13, a current situation during the incidence of a pump light prepulse on a plasma-generating medium in the form of a tin droplet in the plasma source region;

FIG. 15 shows, in an illustration similar to FIG. 14, a current situation during the incidence of a pump light main pulse on the plasma-generating medium in the plasma source region;

FIG. 16 shows an enlarged field facet of the field facet mirror according to FIG. 4 with a ray that is incident centrally on the field facet within an EUV beam path of the illumination optical unit, incident at a first angle of incidence for a first tilt position of the field facet;

FIG. 17 shows, in an illustration similar to FIG. 16, angle of incidence ratios during the incidence of the ray in the case of a different tilt position of the field facet compared to FIG. 16;

FIG. 18 shows a schematic illustration for illustrating geometric angle of incidence ratios on a field facet of the illumination optical unit;

FIG. 19 shows a plan view of one of the field facets, having an optical diffraction grating of the type of FIG. 11 for suppressing different extraneous light wavelengths and/or for suppressing extraneous light in an angle of incidence range between a minimum angle of incidence and a maximum angle of incidence;

FIG. 20 shows, in an illustration similar to FIGS. 6, 9 and 12, a further embodiment of an optical diffraction grating for suppressing extraneous light of exactly one wavelength, embodied as a binary grating;

FIG. 21 shows, in an illustration similar to FIG. 19, a field facet of the field facet mirror according to FIG. 3, having an optical diffraction grating according to FIG. 20;

FIG. 22 shows, in an illustration similar to FIG. 15, ray angle ratios for selected rays of the pump light main pulse in the beam path of an arrangement plane of the field facet mirror;

FIG. 23 shows a plan view of a pupil facet of a further embodiment of a pupil facet mirror of the illumination optical unit, having a grating according to FIG. 20;

FIG. 24 schematically shows a beam path of a full-illumination or radiation channel of the illumination optical unit between one of the field facets and a pupil facet assigned thereto for illustrating an angle of incidence range on the pupil facet;

FIG. 25 shows, in an illustration similar to FIG. 23, a pupil facet, having an optical diffraction grating according to FIG. 11 for suppressing different extraneous light wavelengths and/or for suppressing extraneous light in an angle of incidence range between a minimum angle of incidence and a maximum angle of incidence;

FIG. 26 shows, in an illustration similar to FIG. 24, angle of incidence ratios on the pupil facet when a first field facet is assigned to the pupil facet in a first tilt position of the pupil facet;

FIG. 27 shows the facet arrangement according to FIG. 26, in which another field facet is assigned to the pupil facet and the pupil facet takes a different tilt position;

FIG. 28 shows an enlarged detail of the ray impingement on the pupil facet in the tilt positions according to FIGS. 26 and 27 for illustrating an entire angle of incidence range on the pupil facet due to the different tilt positions and due to an expansion of the field facet;

FIG. 29 shows, in an illustration similar to FIG. 22, an embodiment of the illumination optical unit with field facets and with pupil facets, wherein some of the field facets and some of the pupil facets are embodied to suppress extraneous light of a pump light main-pulse wavelength;

FIG. 30 schematically shows an illustration of the beam path between a condenser mirror of the illumination optical unit and an entrance pupil of a projection optical unit of the projection exposure apparatus for illustrating angles of incidence within the beam path on the condenser mirror;

FIG. 31 shows a section of a further embodiment of a field facet mirror, constructed from a large number of MEMS individual mirrors that are arranged in a grid and divided into modules, wherein additionally shown are peripheral contours of three field facets, which can be formed by a corresponding grouping of the MEMS individual mirrors in this embodiment of the field facet mirror and correspond to the field facets shown above in terms of their function;

FIG. 32 shows, in an illustration similar to FIG. 31, a section of a further embodiment of a pupil facet mirror, the pupil facets of which are in turn formed from MEMS individual mirrors with a corresponding grouping, with peripheral contours of a plurality of these pupil facets, which arise on account of the grouping, being shown by way of example.

### EXEMPLARY EMBODIMENTS

A microlithographic projection exposure apparatus 1 is used to produce a microstructured or nanostructured electronic semiconductor device. A light source 2 emits EUV radiation in the wavelength range, for example, between 5 nm and 30 nm, which is used for illumination. The light source 2 can be a GDPP source (gas discharge produced plasma) or an LPP source (laser produced plasma). EUV illumination light or illumination radiation in the form of an illumination light beam or imaging light beam 3 is used for illuminating and imaging within the projection exposure apparatus 1. The EUV illumination light is also referred to as EUV used light. Exemplary wavelengths for the EUV used light are 13 nm, 13.5 nm, 6.7 nm, 6.9 nm or 7 nm.

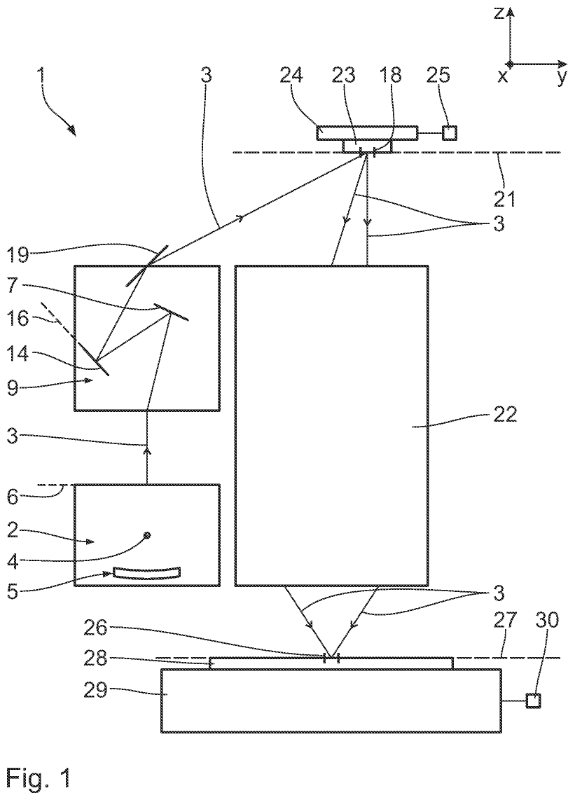

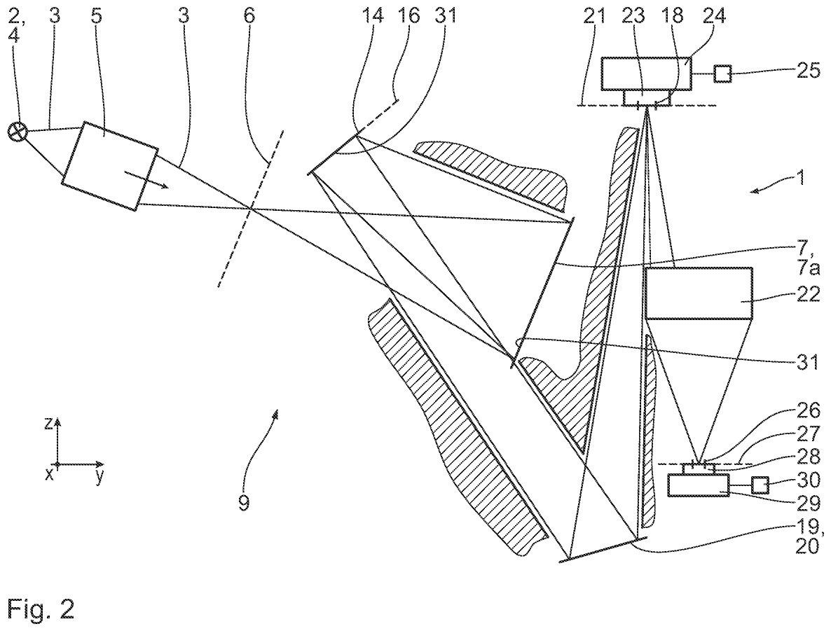

The imaging light beam 3 emanates from a source region 4 of the light source 2 and is initially incident on a collector 5, which can be, for example, a nested collector with a multi-shell structure known from the prior art with mirrors that are operated under grazing incidence of the EUV used light (cf. the schematic illustration according to FIG. 2), or alternatively an ellipsoidally shaped collector arranged behind the light source 2 (cf. the schematic illustration according to FIG. 1 and the illustration according to FIG. 7). After the collector 5, the EUV illumination light 3 first passes through an intermediate focus plane 6, which is used to separate the imaging light beam 3 from undesired radiation or particle components and, for example, to separate the imaging light beam 3 from extraneous light. This separation will be explained below by way of example in connection with FIG. 7.

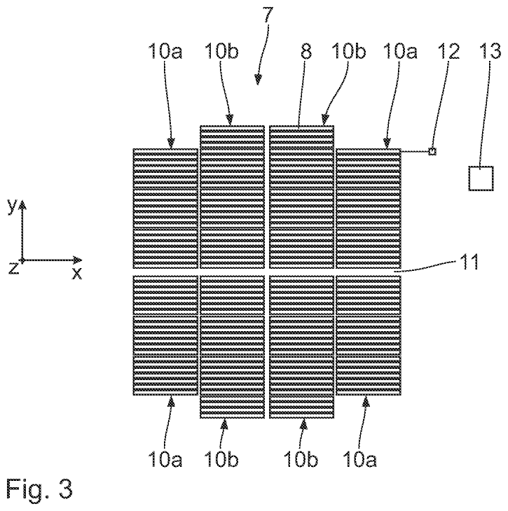

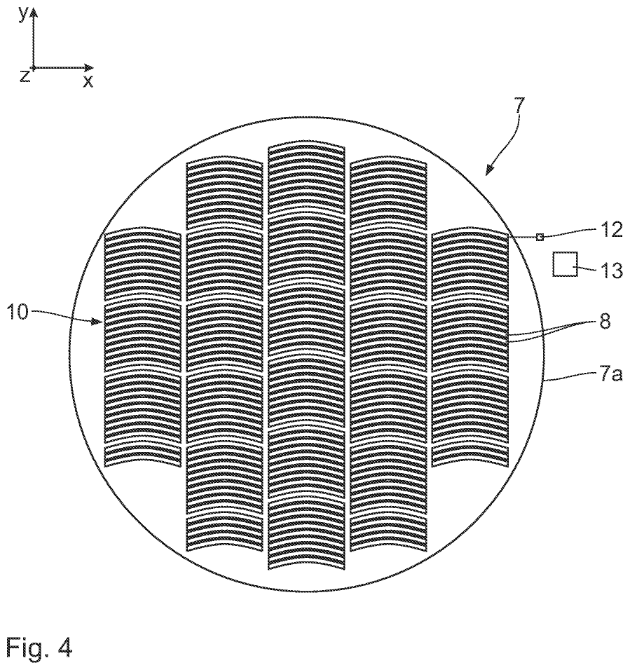

After passing through the intermediate focus plane 6, the imaging light beam 3 is initially incident on a field facet mirror 7. The field facet mirror 7 represents a first facet mirror of the projection exposure apparatus 1 and is part of an illumination optical unit 9 of the projection exposure apparatus 1. The field facet mirror 7 has a plurality of field facets 8 (cf. also FIGS. 3 and 4), which are arranged on a first mirror carrier 7a.

To simplify the description of positional relationships, a Cartesian global xyz-coordinate system is shown in each case in the drawing. The x-axis in FIGS. 1 and 2 extends perpendicular to the plane of the drawing and out of it. The y-axis extends to the right in FIGS. 1 and 2. The z-axis extends upward in FIGS. 1 and 2.

To simplify the description of positional relationships in the case of individual optical components of the projection exposure apparatus 1, a Cartesian local xyz- or xy-coordinate system is used in each of the following figures. Unless otherwise described, the respective local xy coordinates span a respective main arrangement plane of the optical component, for example a reflection plane. The x-axes of the global xyz-coordinate system and of the local xyz- or xy-coordinate systems extend parallel to one another. The respective y-axes of the local xyz- or xy-coordinate systems have an angle with respect to the y-axis of the global xyz-coordinate system that corresponds to a tilt angle of the respective optical component about the x-axis.

FIG. 3 shows, by way of example, a facet arrangement of field facets 8 of the field facet mirror 7 in the “rectangular field” embodiment. The field facets 8 are rectangular and each have the same x/y aspect ratio. The x/y aspect ratio is greater than 2. The x/y aspect ratio can be, for example, 12/5, can be 25/4, can be 104/8, can be 20/1 or can be 30/1.

The field facets 8 define a reflective surface of the field facet mirror 7 and are grouped into four columns of six to eight field facet groups 10a, 10b each. The field facet groups 10a each have seven field facets 8. The two additional peripheral field facet groups 10b of the two middle field facet columns each have four field facets 8. Between the two middle facet columns and between the third and fourth facet rows, the facet arrangement of the field facet mirror 7 has intermediate spaces 11 in which the field facet mirror 7 is shaded by retaining spokes of the collector 5. If an LPP source is used as the light source 2, corresponding shading can also come about due to a tin droplet generator, which is arranged adjacent to the collector 5 and is not shown in the drawing.

The field facets 8 can be switchable in each case between a plurality of different tilt positions, for example switchable between three tilt positions. Depending on the embodiment of the field facet mirror 7, all or some of the field facets 8 can also be switchable between two or between more than three different tilt positions. For this purpose, each of the field facets is connected to a respective actuator 12, which is shown extremely schematically in FIG. 3. The actuators 12 of all tiltable field facets 8 can be controlled via a central control device 13, which is likewise schematically illustrated in FIG. 3.

The actuators 12 can be designed in such a way that they tilt the field facets 8 by discrete tilt contributions. This can be ensured, for example, by tilting between two end stops. Continuous tilting or tilting between a larger number of discrete tilt positions is also possible.

After reflection at the field facet mirror 7, the imaging light beam 3, which is divided into imaging light partial beams that are assigned to the individual field facets 8, is incident on a pupil facet mirror 14 of the illumination optical unit 9. The respective imaging light partial beam of the entire imaging light beam 3 is guided along one imaging light channel in each case, which is also referred to as a radiation channel, as a full-illumination channel or as a field facet imaging channel.

FIG. 4 shows a further embodiment “arc field” of a field facet mirror 7. Components that correspond to those that were explained above with reference to the field facet mirror 7 according to FIG. 3 have the same reference signs and are only explained insofar as they differ from the components of the field facet mirror 7 according to FIG. 3.

The field facet mirror 7 according to FIG. 4 has a field facet arrangement with curved field facets 8. These field facets 8 are arranged in a total of five columns, each with a plurality of field facet groups 10. The field facet arrangement is inscribed in a circular boundary of the mirror carrier 7a of the field facet mirror 7.

The field facets 8 of the embodiment according to FIG. 4 all have the same area and the same ratio of width in the x-direction to height in the y-direction, which corresponds to the x/y aspect ratio of the field facets 8 of the embodiment according to FIG. 3.

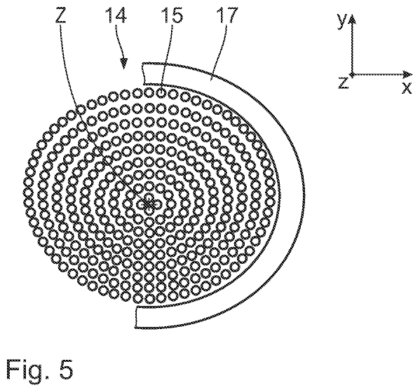

FIG. 5 shows, highly schematically, an exemplary facet arrangement of pupil facets 15 of the pupil facet mirror 14. The pupil facet mirror 14 represents a second facet mirror of the projection exposure apparatus 1. The pupil facet mirror 14 is arranged in a pupil plane 16 of the illumination optical unit 9. The pupil facets 15 are arranged on a carrier plate 17 of the pupil facet mirror 14, which is indicated only in a circumferential section in FIG. 5. The pupil facets 11 are arranged around a facet arrangement center Z on the pupil facet mirror carrier 17.

A pupil facet 15 is assigned to each imaging light partial beam of the EUV illumination light 3, which is reflected by one of the field facets 8, such that in each case an impinged pair of facets with exactly one of the field facets 8 and exactly one of the pupil facets 15 defines the imaging light channel for the associated imaging light partial beam of the EUV illumination light 3.

The channel-wise assignment of the pupil facets 15 to the field facets 8 takes place in dependence on a desired illumination by the projection exposure apparatus 1. Each of the field facets 8 can define different imaging light channels by way of different possible field facet tilt positions. The illumination light partial beams are guided, superposed on one another, into an object field 18 of the projection exposure apparatus 1 via the field facet imaging channels thus defined.

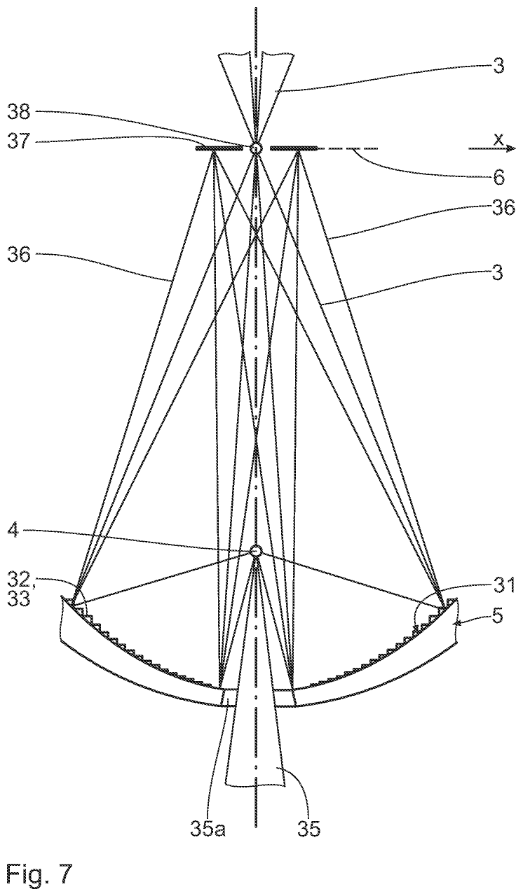

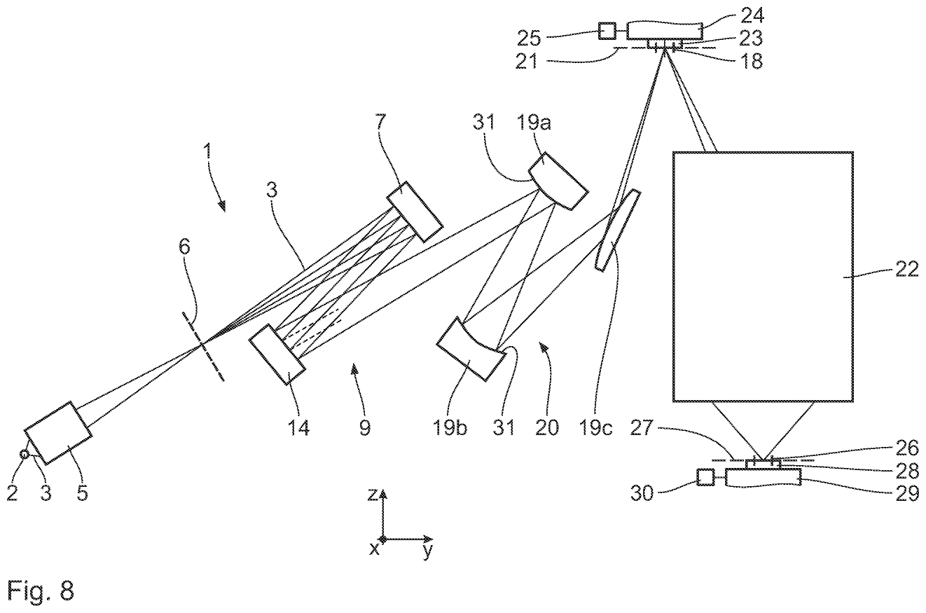

The field facets 8 are imaged into an object plane 21 of the projection exposure apparatus 1 and superposed in the object field 18 via the pupil facet mirror 14 and a subsequent transmission optical unit 20 having a condenser mirror 19. Alternatively, the transmission optical unit 20 can also have further EUV mirrors in addition to the condenser mirror 19, for example two, three or even more than three mirrors (cf. also FIG. 8 in this regard).

In FIG. 1, the condenser mirror 19 is indicated as a mirror for grazing incidence. The embodiment according to FIG. 2 shows the condenser mirror 19 as a mirror with an angle of incidence smaller than 45°.

A variant of the transmission optical unit 20, in which only the respective pupil facet 15 ensures the imaging of the assigned field facet 8 into the object field 18, is also possible. Further components of a transmission optical unit can be dispensed with if the pupil facet mirror 14 is arranged directly in an entrance pupil of a subsequent projection optical unit 22. The transmission optical unit 20 can also have a plurality of mirrors.

In the object plane 21, an object in the form of a lithography mask or a reticle 23 is arranged, of which a full-illumination region is fully illuminated with the EUV illumination light 3, in which the object field 18 of the downstream projection optical unit 22 of the projection exposure apparatus 1 is located. The full-illumination region is also referred to as the illumination field. The object field 18 is rectangular or arcuate, depending on the specific embodiment of the illumination optical unit 9 of the projection exposure apparatus 1. Field facet images of the field facet imaging channels are superposed in the object field 18.

The EUV illumination light 3 is reflected by the reticle 23. The reticle 23 is held by an object holder 24, which is displaceable in a driven manner along the displacement direction y with the aid of a schematically indicated object displacement drive 25.

The projection optical unit 22 images the object field 18 in the object plane 21 into an image field 26 in an image plane 27. In this image plane 27, a wafer 28 is arranged, which carries a light-sensitive layer which is exposed with the projection exposure apparatus 1 during the projection exposure. The wafer 28, i.e. the substrate on which the image is being imaged, is held by a wafer or substrate holder 29, which is displaceable along the displacement direction y with the aid of a wafer displacement drive 30, which is likewise indicated schematically, synchronously with the displacement of the object holder 24. During the projection exposure, both the reticle 23 and the wafer 28 are scanned in a synchronized manner in the y-direction. The projection exposure apparatus 1 is embodied as a scanner. The scanning direction y is the object displacement direction.

The field facet mirror 7, the pupil facet mirror 14, and the condenser mirror 19 of the transmission optical unit 20 are integral parts of the illumination optical unit 9 of the projection exposure apparatus 1. Together with the projection optical unit 22, the illumination optical unit 9 forms an illumination system of the projection exposure apparatus 1.

A respective group of pupil facets 15, which are impinged by the illumination light 3 via corresponding field facets 8 assigned to full-illumination channels, defines a respective illumination setting, i.e. an illumination angle distribution during the illumination of the object field 18, which can be specified via the projection exposure apparatus 1. By switching the tilt positions of the field facets 8, it is possible to switch between different such illumination settings. Examples of such illumination settings are described in WO 2014/075902 A1 and in WO 2011/154244 A1.

In each case one optical diffraction component 31, which is embodied as an optical grating, for suppressing extraneous light radiation having a wavelength deviating from the EUV used light 3 is arranged on at least two of the components that are embodied to be reflective for the EUV used light and that sequentially guide the EUV used light between the source region 4 and the object field 18 and are also referred to as EUV mirror components. The EUV mirror components between the source region 4 and the object field 18 that are available for the arrangement of the optical diffraction component 31 are the EUV collector 5, the field facet mirror 7, the pupil facet mirror 14, and the condenser 19.

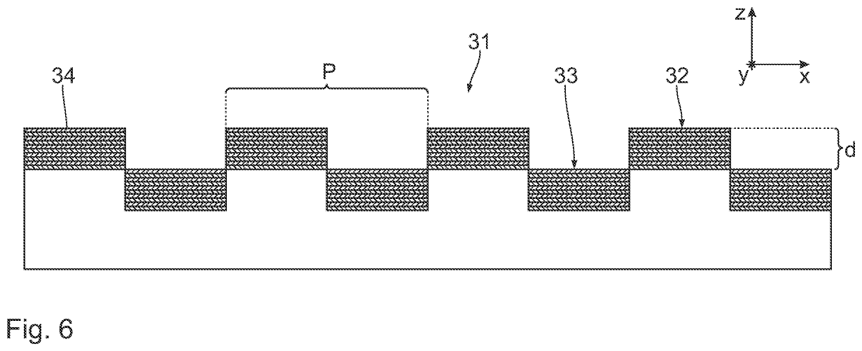

FIG. 6 shows a side view of the optical diffraction component 31, which is embodied as a binary grating with positive diffraction structures 32 (peaks) and negative diffraction structures 33 (valleys). A grating period P of the optical diffraction component 31 and a structure depth d of the binary grating are matched to extraneous light wavelengths to be suppressed in a manner such that the extraneous light can be, for example, diffracted in the +/−first order of diffraction out of the beam path of the EUV used light and, for example, guided away via an extraneous light reflector and/or via a beam dump, i.e. an extraneous light trap.

FIG. 6 shows in a section the periodicity of the diffraction structures 32, 33 of an embodiment of the optical grating 31, which can be used for example in the EUV collector 5. A sectional plane according to FIG. 6 extends in an xz-plane of the coordinate system shown. A grating surface of the optical grating extends parallel to the xy plane in FIG. 6.

The diffraction structures 32, 33 are in section perpendicular to their longitudinal extent y in FIG. 6, that is to say they extend perpendicular to the plane of the drawing in FIG. 6.

The diffraction structures 32, 33 of the optical diffraction component 31 are ineffective for the EUV used light.

The optical diffraction component 31 is highly reflective for the EUV used light. For this purpose, the binary grating structure of the optical diffraction component 31 has a multilayer coating 34, which can be embodied as a plurality or multiplicity of alternating individual layers of different materials whose refractive indices and layer thicknesses are matched to the constructive interference of the EUV used light to be reflected.

FIG. 2 indicates the case in which the two facet mirrors 7 and 14 each carry an optical diffraction component 31. The grating periods of these two optical diffraction components differ due to the adaptation to different extraneous light target wavelengths.

FIG. 7 shows, by way of example, the effect of an optical diffraction component 31 mounted on the collector 5 in the manner of that of FIG. 6 for suppressing extraneous light. Shown is a beam path to and from the source region 4 of the EUV light source 2 and for example the extraneous-light-suppressing effect of the EUV collector 5, which in this case is equipped with the optical diffraction component 31, which is not shown to scale in FIG. 7.

Pump light 35, for example the emission of a CO₂ laser, is focused into the source region 4 and interacts with a target medium (not shown in more detail), which emits EUV used light 3 having an EUV used wavelength, for example of 6.9 nm or 13 nm, and extraneous light 36 having a wavelength that deviates from the EUV used wavelength. Significant portions of the extraneous light 36 have the wavelength of the pump light 35. The pump light 35 passes through a through opening 35a in the collector 5.

Both the EUV used light 3 and the extraneous light 36 are reflected by a mirror surface of the EUV collector 5, which in the embodiment shown carries the optical diffraction component 31.

The diffraction structures 32, 33 are not shown to scale in FIG. 7.

The optical grating 31 serves for the diffractive deflection of the extraneous light 36, so that only the EUV used light 3 passes through an intermediate focus stop 37, which is arranged in the intermediate focus plane 6. The intermediate focus plane 6 represents an image plane of the source region 4. Correspondingly, the mirror surface of the EUV collector 5 has the basic shape of a conic section surface. In the embodiment shown in FIG. 7, the mirror surface has the basic shape of an ellipsoidal surface, in whose one focal point the source region 4 is arranged and in whose other focal point an intermediate focus (IF) 38 lies in the intermediate focus plane 6.

In the embodiment described in connection with FIG. 7, in addition to the collector 5, a further EUV mirror component carries a corresponding optical diffraction component 31 according to FIG. 6 for suppressing extraneous light. For example, the field facets 8 of the field facet mirror 7 can be provided with corresponding diffraction structures 32, 33. Alternatively or additionally, the pupil facets 15 of the pupil facet mirror 14 can be provided with corresponding diffraction structures 32, 33 for suppressing extraneous light. Alternatively or additionally, the condenser mirror 19, either in the embodiment of grazing incidence according to FIG. 1 or in the embodiment for reflection with a smaller angle of incidence according to FIG. 2, can carry corresponding diffraction structures 32, 33 for suppressing extraneous light. At least two of the EUV mirror components 5 (collector), 7 (field facet mirror), 14 (pupil facet mirror) and 19 (condenser) are provided with an optical diffraction component 31 with corresponding diffraction structures for suppressing extraneous light. The effect of the optical diffraction component 31 on the field facet mirror 7 and/or on the pupil facet mirror 14 and/or on the condenser mirror 19 corresponds, apart from the design to be explained below for a different extraneous light wavelength, to that which was described above in connection with FIG. 7 and the collector 5. Even when applied to one of the other EUV mirror components 7, 14 or 19, the optical diffraction component 31 mounted there diffracts extraneous light having a wavelength deviating from the EUV used light out of the beam path of the EUV used light.

The optical diffraction components 31, which are mounted on at least two of the different EUV mirror components 5, 7, 14, 19, are designed to suppress different extraneous light wavelengths. For example, the optical diffraction component 31 can be designed to suppress extraneous light having a wavelength of a main pulse of the light source 2 embodied as an EUV plasma source. The optical diffraction component 31 on at least one further EUV mirror component, for example on the field facet mirror 7, can then be embodied to suppress another extraneous light wavelength, e.g. that of a prepulse of the EUV plasma source. The wavelength of the main pulse can be 10.6 μm, for example. The wavelength of the prepulse can be 10.2 μm, for example.

Each of the optical diffraction components 31 on the different EUV mirror components 5, 7, 14, 19 can have exactly one specific target wavelength for suppressing extraneous light. Alternatively, each of these optical diffraction components 31 on the different EUV mirror components 5, 7, 14, 19 can have its own main target wavelength, but also additionally suppress further secondary wavelengths.

Apart from the two EUV mirror components which each have the optical diffraction component 31 for suppressing extraneous light, the others of the EUV mirror components in the beam path between the source region 4 and the object field 18 can be embodied without such optical diffraction components.

A further embodiment of a projection exposure apparatus 1, again with an illumination optical unit, is described below with reference to FIG. 8. Components and functions that correspond to those that have already been explained above with reference to FIGS. 1 to 7 have the same reference signs and will not be discussed again in detail.

Instead of a single condenser mirror, the transmission optical unit 20 according to FIG. 8 has a total of three EUV mirrors 19a, 19b and 19c for imaging the field facets of the field facet mirror 7 into the object plane 21. The two EUV mirrors 19a, 19b are embodied as NI (normal incidence) mirrors with an angle of incidence of the illumination light 3 that is less than 45°. The EUV mirror 19c is embodied as a GI (grazing incidence) mirror with an angle of incidence of the illumination light 3 that is greater than 45°. The transmission optical unit 20 with the mirrors 19a, 19b and 19c can also ensure imaging of an illumination pupil plane in the region of an arrangement plane of the pupil facet mirror 14 into an entrance pupil of the projection optical unit 22. Such a structure of an illumination optical unit is known in principle from DE 10 2015 208 571 A1.

In the embodiment of the illumination optical unit 9 according to FIG. 8, the two EUV mirrors 19a and 19b each carry one of the optical diffraction components 31 for suppressing the different EUV target wavelengths, that is to say for suppressing extraneous light. In other variants of this illumination optical unit 9 according to FIG. 8, two other ones of the EUV mirror components 7, 14, 19a, 19b and 19c can also carry corresponding optical diffraction components 31. Variants in which more than two or all of the EUV mirror components 7, 14, 19a, 19b and 19c carry corresponding optical diffraction components 31, of which at least two have their own target wavelength for suppressing extraneous light, are also possible. What has already been explained above with regard to the embodiments according to FIGS. 1 to 7 applies here accordingly.

A first direction of incidence of the illumination light 3 after reflection at the collector 5 can, as is shown in the embodiment according to FIG. 1, be obliquely from above or, as is shown in FIG. 8, be obliquely from below. A direction of incidence for example perpendicular from above or perpendicular from below is also possible, which is then correspondingly transferred by the respective illumination optical unit 9 into the direction of incidence for illuminating the object field 18.

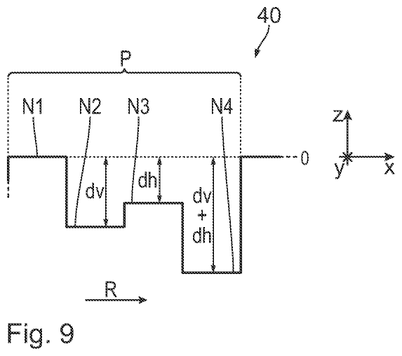

FIG. 9 shows a further embodiment of an optical diffraction component 40 in a sectional illustration, which is comparable with that according to FIG. 6. The diffraction grating 40 has successive diffraction structure levels within a grating period P along a period extent direction R, which extends parallel to the x-direction: N1 with a structure depth 0, N2 with a structure depth dv, N3 with a structure depth dh, and N4 with a structure depth dv+dh. The following applies: dh<dv. The following applies: dv+dh>dh, dv>0. The same structure depth difference dv therefore exists between the levels N1 and N2 and between N3 and N4. In each case the same structure depth difference dh exists between the levels N1 and N3 and between N2 and N4. The diffraction grating 40 thus has a total of four diffraction structure levels N1 to N4, which differ in terms of their structure depths.

The levels N1 to N4 represent structure sections of the diffraction grating 40, the extent of which along the extent direction R is in each case P/4.

By appropriately designing the structure depths dv and dh, the diffraction grating 40 can be used to suppress different extraneous light wavelengths λ1, λ2, for example suppress a wavelength λ1 of a pump light prepulse of the plasma light source 2 of for example 10.2 μm and the wavelength λ2 of a pump light main pulse of the light source 2 for example of 10.6 μm.

In the diffraction grating 40 according to FIG. 9, the different diffraction structure levels N1 to N4 lie next to one another along the extent direction R.

The diffraction grating 40 can be used in place of one of the optical diffraction components that were discussed above. In addition, the diffraction grating 40 can be equipped with additional components and functions, for example with a multilayer coating in accordance with what has already been explained above with regard to the other diffraction gratings. This also applies accordingly to the diffraction grating embodiments described below.

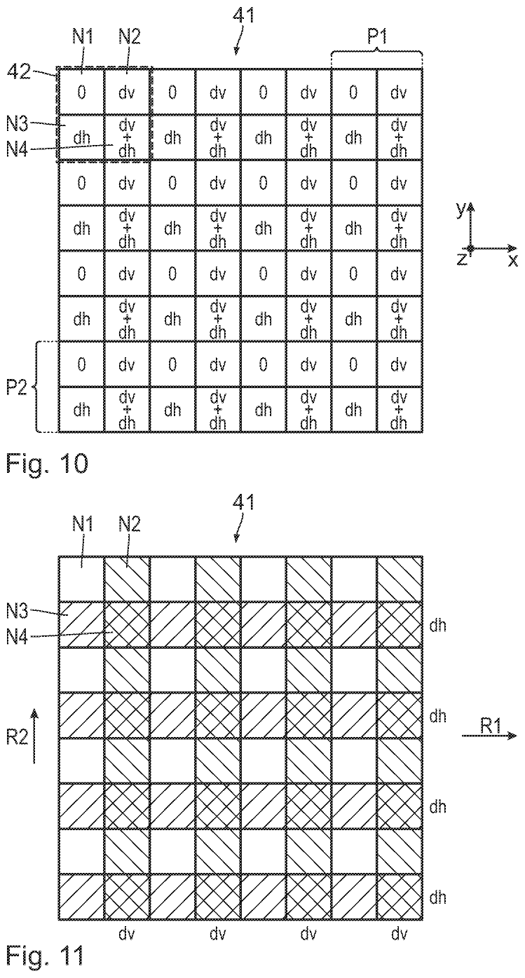

FIG. 10 shows a further embodiment of an optical diffraction component in the form of a diffraction grating 41, which can be used for example instead of the diffraction grating 40 according to FIG. 9.

The diffraction grating 41 is divided into structure sections with diffraction structure levels N1, N4, the structure depths of which correspond to those which have already been explained above in connection with FIG. 9.

In the diffraction grating 41, two gratings with periods P1 and P2 with extent directions in the x-direction (grating period P1) and the y-direction (grating period P2) are superposed. The result is a grid-type or checkerboard-type arrangement of the diffraction structure levels N1 to N4, which can be understood as several 2×2 grid cells joined together, with one of these grid cells 42 being highlighted in FIG. 10 with a dashed line. This grid cell 42 has in the first row on the left the following structure level N1 with a structure depth 0 and on the right the diffraction structure level N2 with a structure depth dv and in the second row on the left the diffraction structure level N3 with a structure depth dh and on the right the diffraction structure level N4 with a structure depth dh+dv.

A diffraction effect of the diffraction grating 41 can in turn be used to suppress extraneous light from a plurality of different extraneous light wavelengths.

FIG. 11 shows an alternative illustration of the diffraction grating 41 for illustrating the grid arrangement of the different diffraction structure levels N1 to N4.

The diffraction gratings 40 and 41 can be produced by two sequential etching processes. At the location of the diffraction structure levels N1, using appropriate masks, no etching is performed, at the location of the diffraction structure levels N2 and N4 with the structure depth dv and at the location of the diffraction structure levels N3 and N4 with the structure depth dh etching is performed, wherein in turn corresponding masks are used and wherein only the diffraction structure levels N4 are subjected to both etching steps, so that the total structure depth dh+dv is generated there.

dv can be in the region of 2.65 dh can be in the region of 2.55 The partial grating with the structure depth difference dv can thus be used to suppress the extraneous light wavelength 10.6 and the partial grating with the structure depth difference dh can be used to suppress the extraneous light wavelength 10.2 μm.

To include an additional dependence of the structure depths dv and dh on the angle of incidence of the incident extraneous light radiation, the diffraction gratings, for example the diffraction grating 41, can be embodied with a structure depth that varies over an area of the respective EUV mirror component. This structure depth variation can take place in the form of a gradation or continuously.

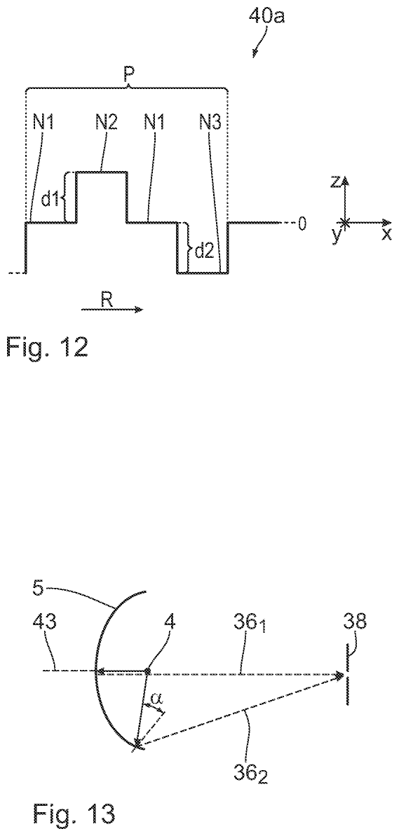

In an illustration similar to FIG. 9, FIG. 12 shows a further embodiment of an optical diffraction component in the form of a diffraction grating 40a, which can be used as an alternative or in addition to the diffraction grating 40 or the other diffraction gratings explained above.

The diffraction grating 40a has a total of three types of diffraction structure levels N1, N2 and N3 within a grating period P, which each have a structure section length of P/4 within the grating period P along the extent direction R. The diffraction structure level N1 is embodied as a neutral structure section. The diffraction structure level N2 is embodied as a positive structure section, the structure depth of which differs from the neutral structure section N1 by a value d1. The diffraction structure level N3 is embodied as a negative structure section, the structure depth of which differs from that of the neutral structure section N1 by a value d2. The structure depths d1 and d2 can differ, but may also be identical. What has been stated above for the structure depths dv, dh of the diffraction grating 40 can apply to absolute values of the structure depths d1, d2. Within the grating period P, the sequence of the diffraction structure levels can be N1, N2, N1 and N3, as in FIG. 12. Another sequence of the diffraction structure levels is also possible, wherein the neutral structure section N1 has a total of twice the length, namely P/2.

If a diffraction grating with more than two diffraction structure levels is used, the different structure depths can be embodied to suppress different, closely located wavelengths in order to optimize an overall suppression of extraneous light.

In order to suppress pump light having a wavelength of 10.60 μm, for example, a diffraction grating with two structure depths dv, dh or d1, d2 can be used, which are designed for wavelengths 10.59 μm and 10.61 μm and which can, for example, be 2.6475 μm and 2.6525 μm.

A diffraction grating with more than two diffraction structure levels can also be used to improve a suppression bandwidth if only one target wavelength is to be suppressed in order to improve an angle of incidence tolerance.

The etching depths dv, dh or d1, d2 of the gratings 40, 40a, 41 can be a quarter of the extraneous light wavelength to be suppressed.

This angle of incidence dependence is illustrated with reference to FIG. 13. Here, a beam path of two different extraneous light rays 36₁, 36₂, for example of the pump light prepulse, is shown. Entry of the pump light through a through opening (not shown in FIG. 13) (cf. through opening 35a in FIG. 7) in the collector 5 is not shown in FIG. 13.

The extraneous light ray 36₁ is the result of the back-reflection of the pump light prepulse toward the reflective surface of the collector 5, wherein the back-reflection takes place in the source region 4. The back-reflected extraneous light ray 36₁ is incident on the reflective surface of the collector 5 perpendicularly, that is to say at an angle of incidence of 0°, and is reflected from there, provided no extraneous light suppression takes place, toward the intermediate focus 38, where it passes through the source region 4. The further extraneous light ray 36₂, which is shown in FIG. 13, is deflected from the source region 4 at a deflection angle of almost 90° to the reflective surface of the collector 5 and is incident on the reflective surface of the collector 5 at an angle of incidence α of about 30°.

When the collector 5 is equipped with an optical diffraction component for suppressing extraneous light, for example the diffraction grating 41 with structure depths dv, dh that are adapted to the respective angle of incidence α thus lies in concentric surface sections of the collector 5 around a central axis of rotational symmetry 43. The etching depths dh, dv is increased in accordance with the cosine of the angle of incidence.

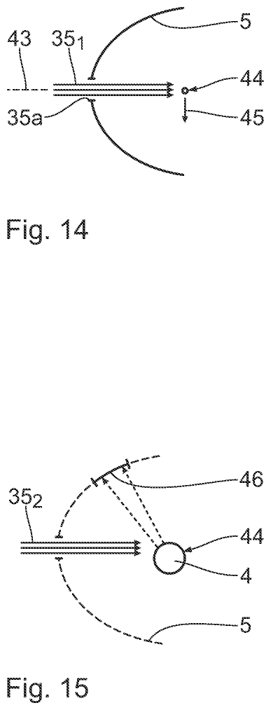

FIG. 14 illustrates the irradiation conditions within the plasma light source 2 when the pump light prepulse 35₁ is incident on the plasma-generating medium in the form of a tin droplet 44. The pump light prepulse 35₁ passes through the through opening 35a of the collector 5, travels along the axis of rotational symmetry 43 and is incident in the source region 4 on the tin droplet 44, which is moving in a direction of movement 45 perpendicular to the axis of rotational symmetry 43.

FIG. 15 shows the irradiation conditions of the pump light main pulse 35₂, which arrives in the source region 4 after the tin droplet 44 was vaporized by the prepulse. The pump light main pulse 35₂ is incident eccentrically on the tin droplet 44 relative to the tin droplet 44, with the result that the pump light main pulse 35₂ is reflected by the tin droplet 44 mainly in the direction of an eccentric collector section 46 of the collector 5. The collector section 46 has an area which is smaller than, for example, one tenth of the total reflective surface of the collector 5. The collector section 46 is delimited both within the meridional plane, that is to say the plane of the drawing in FIG. 15, and in the circumferential direction around the axis of rotational symmetry 43. A similar effect can occur if the tin droplet 44 is struck on the optical axis, but the tin droplet does not have an exactly spherical shape.

The collector 5 can be embodied in such a way that a first type of an optical diffraction component, for example a first grating type, is present in the collector section 46 and the remaining reflective surface of the collector 5 is equipped with a second type of an optical diffraction component, for example with a second grating type. Alternatively, the remaining reflective surface of the collector 5 can also be equipped without a diffraction component for suppressing extraneous light.

The first grating type can be embodied as a multiple grating in the manner of the diffraction gratings 40, 40a, 41 both for the prepulse wavelength and the main-pulse wavelength. Alternatively, the first grating type can be embodied exclusively to suppress the main-pulse wavelength.

The second grating type outside the collector section 46 can be used only to suppress the prepulse wavelength, or it can likewise be embodied as a multiple grating for both wavelengths. Any desired variants of these two types of gratings in the collector section 46 and in the remaining reflective surface region of the collector 5 are possible.

If one of the two types of grating is designed for only exactly one pump light wavelength, this grating can for example be embodied as a binary grating in the manner of the optical diffraction component 31.

The different types of gratings that can be used in the different surface sections of the reflective surface of the collector 5 can be optimized, depending on the incident extraneous light to be expected, for the suppression of the latter and/or for a reflectivity for the EUV used light.

A diffraction grating adapted to the angles of incidence with regard to the extraneous light suppression, as stated above in connection with FIG. 13, is an example of the design of an optical diffraction component such that the extraneous light radiation is suppressed in an entire angle of incidence range between a minimum angle of incidence and a maximum angle of incidence. A suppression ratio between an intensity of the extraneous light incident on the diffraction grating and an intensity of the extraneous light emerging in the direction of the beam path for the EUV used radiation can be better than 1000 and can for example be better than 10⁴ or 10⁵.

In the following, further embodiments of variants of optical diffraction components will be explained, which are designed to suppress extraneous light in an angle of incidence range between a minimum and a maximum angle of incidence.

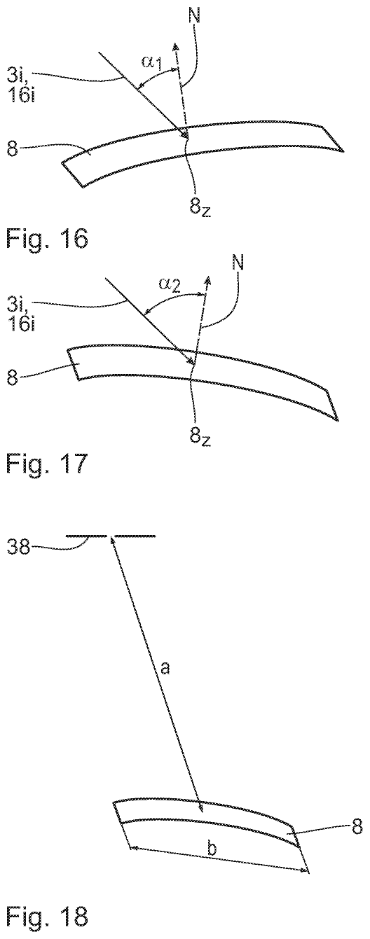

FIG. 16 shows one of the field facets 8 of the field facet mirror 7 according to FIG. 4. An incident light ray, which can be illumination light 3i and/or extraneous light 16₁ and which is guided along the beam path of the illumination optical unit 9, is incident on a center 8_{z} of the field facet 8 at an angle of incidence α₁ with respect to a normal N to the reflective surface of the field facet 8 in the region of the center 8_{z}.

FIG. 17 shows the field facet 8 in a tilt position that is tilted in comparison with FIG. 16 and into which the field facet was tilted by actuation of the actuator 12 assigned to it. In this tilt position according to FIG. 17, the light ray 3i, 16i is incident on the reflective surface of the field facet 8 at an angle of incidence α₂ that is larger in comparison with the angle of incidence α₁ according to FIG. 16.

The angles of incidence α₁, α₂ are shown greatly exaggerated in FIGS. 16 and 17. The angle of incidence α₁ can for example be 8°, and the angle of incidence α₂ can be 12°. Depending on these angles of incidence, wavelengths to be suppressed effectively taking into account the angle of incidence are then, rather than the actual wavelengths λ1 of 10.2 μm and λ2 of 10.6 μm.

in the tilt position according to FIG. 16 (angle of incidence α₁):
10.2 μm/(cos 8°)=10.3 μm,
10.6 μm/(cos 8°)=10.7 μm,
   and in the tilt position according to FIG. 17 (angle of incidence α₂):
10.2 μm/(cos 12°)=10.43 μm,
10.6 μm/(cos 12°)=10.84 μm.

To suppress these effective wavelengths, which lie in the range between 10.3 μm and 10.84 μm, the field facet 8 can be embodied with a diffraction grating 40, 40a, 41 according to the type of FIGS. 9 to 12 with more than two diffraction structure levels for suppressing a plurality of extraneous light wavelengths, wherein, for example, the design may be such that the first of the extraneous light wavelengths to be suppressed is nominally 10.30 μm and the second of the two extraneous light wavelengths to be suppressed nominally is nominally 10.84 μm. Etching depths dh, dv or d1, d2 can then be 2.575 μm and 2.709 μm.

Alternatively, the grating, which has at least three diffraction structure levels Ni, can also be designed to suppress exclusively the angle of incidence range for the wavelength of the pump light main pulse, which in the above example results in structure depths of 10.6 μm/(cos 8°)=10.7 μm and 10.6 μm/(cos 12°)=10.84 μm and corresponding etching depths di of 2.676 μm and 2.709 μm.

In addition to the influence of the field facet tilt angle on the angle of incidence α, the point of incidence of the respective light ray 3i, 16i on the field facet 8 also has an influence on the angle of incidence. FIG. 18 illustrates the dimensions to be taken into account here. A distance a between the intermediate focus 38 and an arrangement plane of the field facet mirror 7, illustrated by a single field facet 8, can be in the region of 1,500 mm. An x-extension b of the respective field facet can be 75 mm. There is a variation in the angle of incidence, depending on the point of incidence of the light ray on the respective field facet 8, in the range of 50 mrad, that is to say in the range of just under 3°. This variation in the angle of incidence can also be taken into account when designing the structure depths d or di of the diffraction gratings. The diffraction grating can for example be designed in such a way that the etching depths di vary over the reflective surface of the field facet 8.

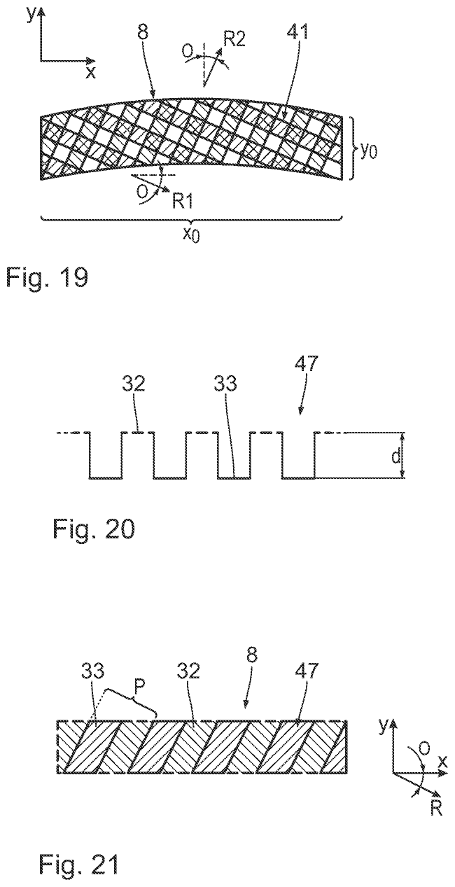

FIG. 19 shows one of the field facets, having a diffraction grating of the type of the diffraction grating 41. Period extent directions R1, R2 along the rows and columns of the grid arrangement of the structure sections of the diffraction grating 41 extend in the xy-plane (y=scanning direction) to the x, y-coordinate directions at an orientation angle θ of approximately 30°. This ensures that diffraction effects of the diffraction grating 41 average out during a scan of an object point through the object field and no undesired systematic diffraction structure effect results over the x object field coordinate.

The grating periods P1, P2 of the diffraction grating 41 are smaller than the extents x₀, y₀ of the field facet 8 in the x- and y-directions. This ensures a sufficient diffraction efficiency of the diffraction grating 41 on the field facet 8 in the case of extraneous light suppression due to destructive interference.

An orientation angle O between the period extent directions R1, R2 and the coordinates x, y of the field facet 8 can lie in the range between 10° and 80°, for example in the range between 20° and 70°, and, for example, be 30° or 60°. When using a diffraction grating with a period extent direction, an orientation of the period extent direction with respect to the scanning direction y should in each case extend at an orientation angle different from 90° and/or different from 0°.

A two-stage grating, for example in the form of a binary grating, can be used to suppress exclusively one extraneous light wavelength, for example the wavelength of the pump light main pulse. An embodiment of such a binary grating has already been explained above in connection with FIG. 6.

FIG. 20 shows a further embodiment of an optical diffraction component for suppressing extraneous light in the form of a diffraction grating 47 embodied as a binary grating.

A structure depth or etching depth d is present between the positive diffraction structures 32 and the negative diffraction structures 33. To suppress an extraneous light wavelength of 10.6 μm, the structure depth d is, at an average angle of incidence of the extraneous light on an EUV mirror component equipped with the diffraction grating 47 of 10°, d=λ_{eff}/4 with λ_{eff}=10.6 μm/(cos 10°). The result is a structure depth d of 2.691 μm.

FIG. 21 shows a field facet 8 in the manner of the field facets of the field facet mirror according to FIG. 3, equipped with the diffraction grating 47 according to FIG. 20. The period extent direction R of the diffraction grating 47 again encloses an orientation angle O of approximately 30° with the x-coordinate of the field facet 8.

The ratio x₀/P between the x-extent x₀ of the field facet 8 and the period P of the diffraction grating 47 is approximately 5/1.

Not all field facets of the field facet mirror 7 have to be equipped in the same way with optical diffraction components for suppressing extraneous light. For example, it is possible for only a subgroup of all the field facets 8 within an arrangement subregion 48 of the field facets 8 of the field facet mirror 7 to be embodied with a diffraction grating for suppressing the pump light wavelength.

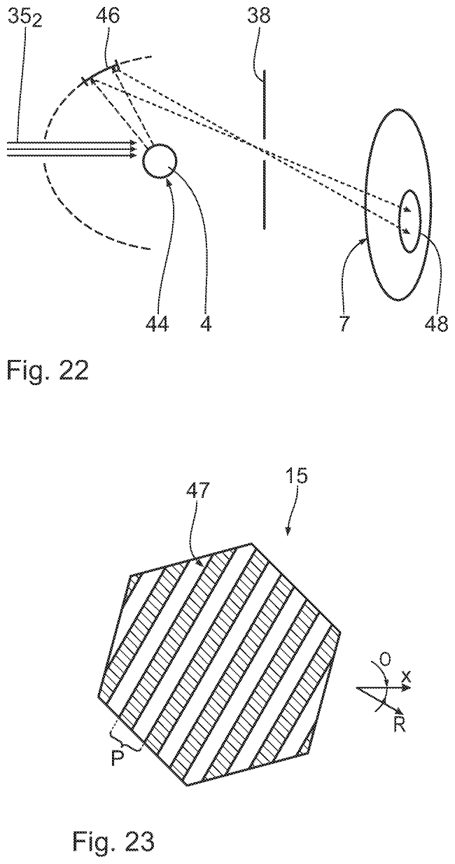

FIG. 22 illustrates the selection of the arrangement subregion 48 within an entire facet arrangement region of the field facet mirror 7. The arrangement subregion 48 is specified in such a way that it covers those field facets 8 which lie in the region of the beam path of the pump light main pulse 35₂. The field facets lying in the arrangement subregion 48 are in turn equipped with an optical diffraction component, for example with the diffraction grating 47 according to FIG. 20, to suppress the wavelength of the pump light main pulse. Other field facets outside the arrangement subregion 48 can be equipped with other types of field facets, which either do not have an optical diffraction component for suppressing extraneous light or have other types of optical diffraction components which can have a higher reflectivity for the EUV used light 3.

FIG. 23 shows a pupil facet 15, which can be used instead of the round pupil facets in the pupil facet mirror 14 according to FIG. 5. The pupil facet 15 according to FIG. 23, in turn, carries an optical diffraction component for suppressing extraneous light. In the embodiment according to FIG. 23, this is the binary diffraction grating 47, which has already been described above in connection with FIGS. 20 and 21. In the case of the diffraction grating 47 for the pupil facet 15, too, a period extent direction R extends at an orientation angle O, which can be, for example, 30°, with respect to the x-coordinate.

A typical diameter of the pupil facet 15 is approximately five to ten times the size of the grating period P of the diffraction grating 47.

The pupil facets 15 can also be equipped with optical diffraction components in the form of diffraction gratings, in which an angle of incidence range between a minimum and a maximum angle of incidence of the incident radiation is taken into account.

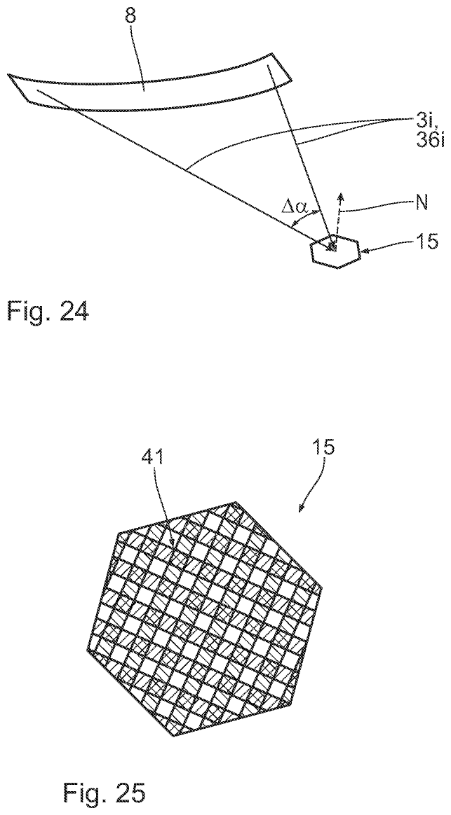

FIG. 24 shows part of a beam path of an illumination or full-illumination channel between one of the field facets 8 and a pupil facet 15 assigned to it. Two individual rays 3i, 16i and 3j, 16j emanating from opposite peripheral regions of the field facets 8 are shown by way of example. These individual rays mark peripheries of an angle of incidence interval Δα of angles of incidence on the pupil facet 15. Taking into account the respective extent of the reflective surface of the field facet 8 and the distance between the field facet 8 and the associated pupil facet 15, this angle of incidence interval Δα lies in the range between 30 mrad and 50 mrad, i.e. in the range of approximately 2°. This angle of incidence interval and the resulting angle of incidence range between a minimum angle of incidence and a maximum angle of incidence on the pupil facet 15 can be taken into account when designing an optical diffraction component with which the pupil facet 15 is equipped, for example an embodiment of a diffraction grating according to the variants described above, as already explained above in connection with the equipment of the field facets 8.

FIG. 25 shows one of the pupil facets 15 with a diffraction grating 41 of the type that has been explained above in connection with FIGS. 10 and 11. Extent directions R1, R2 are again tilted with respect to the x- and y-coordinates of the pupil facet 15, as has already been explained above in connection with the field facet 8 in FIG. 19. A ratio between a period P1, P2 and a typical diameter of the pupil facet 15 can lie in the range between ⅓ and 1/15.

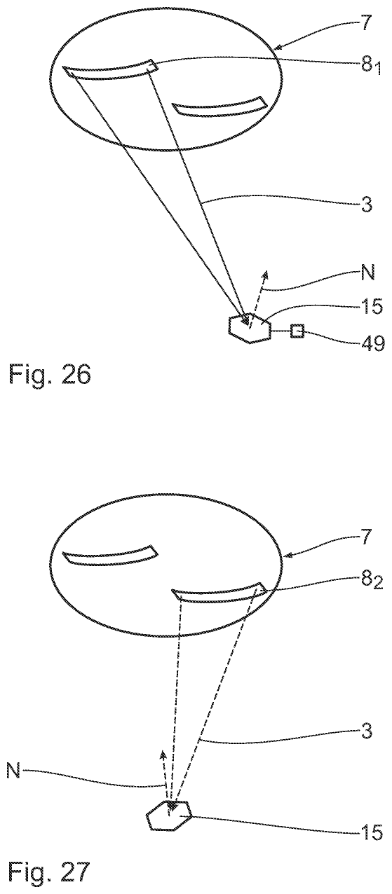

A tiltability of the pupil facets 15 that is possible in principle can have additional influence on an angle of incidence interval Δα on the pupil facet 15 for designing the respective optical diffraction component for suppressing extraneous light, as will be explained below with reference to FIGS. 26 to 28. Comparable with the tiltable field facets 8, the tiltable pupil facet 15 according to FIG. 26 has a tilt actuator 49, which is operatively connected to the respective pupil facet 15.

FIG. 26 shows a first full-illumination channel assignment between a field facet 8₁ of the field facet mirror 7 and the pupil facet 15. The pupil facet 15 is in a first tilt position for reflecting the illumination light 3, which is guided via the full-illumination channel. A first angle of incidence interval results due to the expansion of the field facet 8₁ corresponding to what has already been explained above in connection with FIG. 24.

FIG. 27 shows another facet assignment, in which the pupil facet 15 is assigned a different field facet 8₂ via a full-illumination channel for guiding the illumination light 3. The pupil facet 15 is then in a different tilt position in comparison with FIG. 26, which leads to a different angle of incidence interval of the illumination light 3 incident on the pupil facet 15 and of the extraneous light which may be carried along.

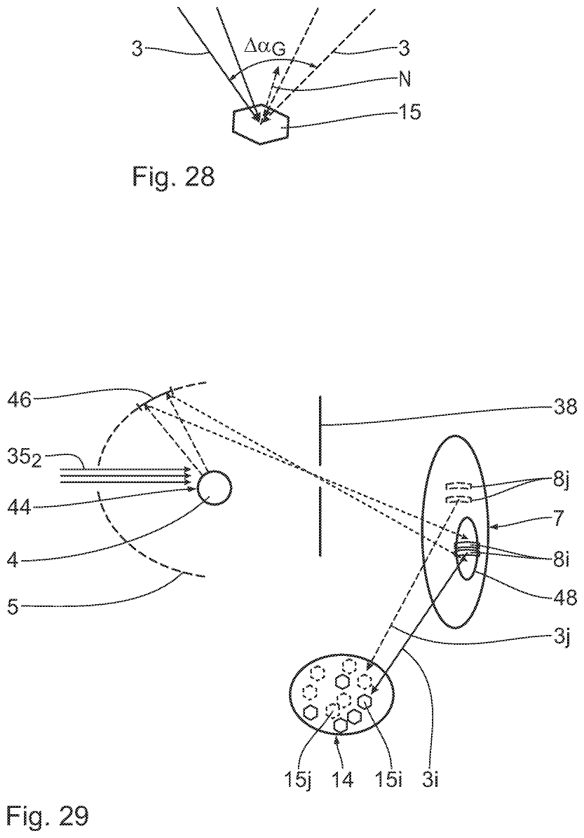

FIG. 28 shows the resulting total angle of incidence interval Δα_{G}, which is taken into account when designing the switchable or tiltable pupil facet 15 due to the tilt positions according to FIGS. 26 and 27. This total angle of incidence interval can lie in the range between 4° and 15°. To suppress the two extraneous light wavelengths of 10.2 μm and 10.6 μm, a first structure depth dh or dl of ¼×10.2 μm/(cos 4°)=10.225 μm/4 and a structure depth dv or d2 of ¼×10.6 μm/(cos 15°)=10.974 μm/4 can then be selected.

FIG. 29 shows an expansion of the concept “facets with different diffraction grating types,” which has been explained above in connection with FIG. 22. In addition to the use of field facets 8i, 8j of two different diffraction suppression types i and j, correspondingly assigned pupil facet types 15i, 15j can be used, which likewise differ in terms of the diffraction suppression type. The field facets 8i, which in the example according to FIG. 29 are arranged within the arrangement subregion 48 of the field facet mirror 7, can be assigned, via corresponding full-illumination channels 3i, the pupil facets 15, the optical diffraction components of which are designed to suppress the pump light main pulse wavelength. For the assignment of the grating types i, j, what was stated above in connection with the grating types 1 and 2 (first and second grating types) of the diffraction gratings of the reflector 5 according to FIG. 15 may apply.

The condenser mirror 19 can also be provided with an optical diffraction component in the form of a diffraction grating, the suppression effect of which is designed for an angle of incidence range of the incident radiation between a minimum angle of incidence and a maximum angle of incidence.

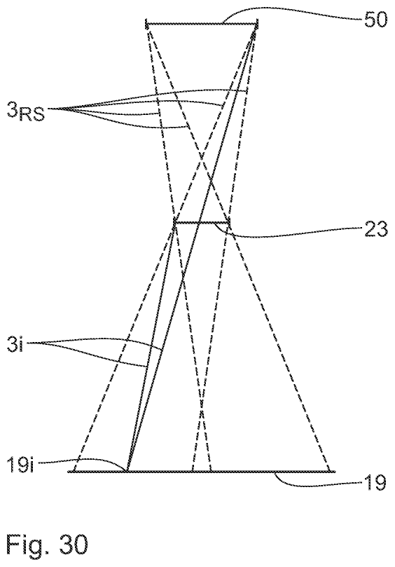

FIG. 30 shows a geometric illustration of part of the beam path of the EUV radiation as well as the extraneous light radiation that may be carried along between the condenser mirror 19 and an entrance pupil 50 of the projection optical unit 22. The reticle 23 lies between the condenser mirror 19 and the entrance pupil 50. The entrance pupil 50 can also have a different position relative to the condenser mirror 19 and to the reticle 23 than shown in FIG. 30.

Marginal rays 3s of the EUV beam path are shown in dashed lines in FIG. 30, which pass through peripheral point pairs of the reticle 23 and of the entrance pupil 50 in the meridional section shown in FIG. 30. In FIG. 30, exemplary individual rays 3i are shown in solid lines, which emanate from exactly one specific point 19i on the condenser mirror and are parts of the EUV beam path and represent the minimum angle of incidence and the maximum angle of incidence on the condenser mirror 19. The two rays 3i are therefore a measure of an angle of incidence range that is covered for extraneous light suppression by an optical diffraction component, for example one of the variants of the optical diffraction gratings, which have been discussed above, for extraneous light suppression.

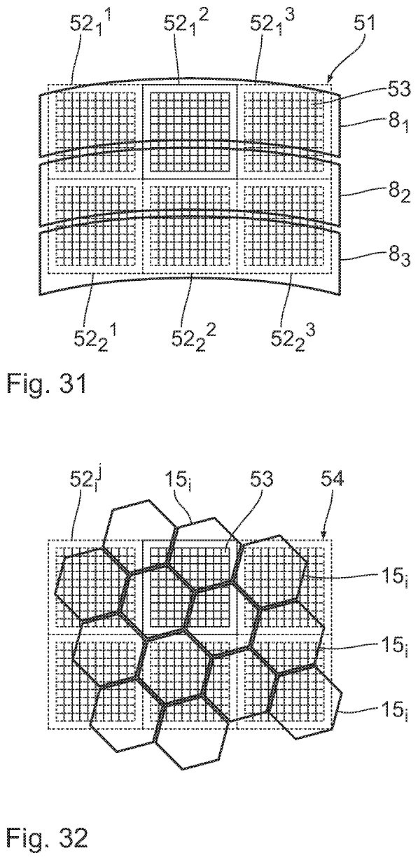

FIG. 31 shows a section of a field facet mirror 51, which can be used instead of the field facet mirrors 7 explained above within the illumination optical unit 9 of the projection exposure apparatus 1. The illustrated section of a facet arrangement of the field facet mirror 51 is divided into a total of six individual mirror modules 52₁¹ to 52₂³, wherein the indexing 52ᵢ^{j} indicates the position of the individual mirror module 52ᵢ^{j} within a grid of i-rows and j-columns. Each of the individual mirror modules 52 in turn has a 10×10 grid of individual mirrors 53, which can be embodied as MEMS individual mirrors. The number of the individual mirrors 53 of each individual mirror module 52 can also be greater, and the individual mirrors can be arranged in a 25×25 grid, for example.

Via the illustrated section of the field facet mirror 51, for example three field facets 8₁, 8₂ and 8₃, also known as virtual field facets, can be generated, at least for the most part, by a corresponding grouping and interconnection of the individual mirrors 53 of the various individual mirror modules 52ᵢ^{j}.

Each of the individual mirror modules 52 can be equipped with its own optical diffraction component for suppressing extraneous light in accordance with what has already been explained above in connection with the other field facet variants. For this purpose, an angle of incidence range of the extraneous light on the respective individual mirror module 52ᵢ^{j} can be estimated or calculated in advance.

In an illustration similar to FIG. 3, FIG. 32 again shows six individual mirror modules 52ᵢ^{j} of a pupil facet mirror 54, which can be used instead of the pupil facet mirror 14 in the illumination optical unit 9 of the projection exposure apparatus 1.

By assigning and interconnecting grouped individual mirrors 53 of the individual mirror modules 52ᵢ^{j}, pupil facets 15i can again be generated, which are indicated in FIG. 32 by a hexagonal arrangement. Even when using the individual mirror modules 52ᵢ^{j} as integral parts of the pupil facet mirror 54, these individual mirror modules 52ᵢ^{j} can again be equipped with optical diffraction components in the manner of the diffraction gratings explained above for suppressing extraneous light.

Instead of an illumination optical unit with a field facet mirror and a pupil facet mirror, a specular reflector can also be used, in which for example a second facet element, which is used after a facet element in the manner of the field facet mirror, is not arranged in the region of a pupil plane of the illumination optical unit. A specular reflector is described, for example, in U.S. Pat. No. 8,934,085 B2, in US 2006/0132747 A1, in EP 1 614 008 B1 and in U.S. Pat. No. 6,573,978. When using such a specular reflector, second facets which are equipped with an optical diffraction component in the manner of one of the diffraction gratings explained above for suppressing extraneous light can also be used.

The entire surface of the EUV mirror components described above, or, alternatively, only sections of their respective reflective surface, may be provided with at least one optical diffraction component for suppressing extraneous light. For example, when the facet mirrors are equipped with an optical diffraction component, it is possible not to equip all facets in the same way or not to equip some facets with an optical diffraction component. The EUV mirror components or individual or all facets may also be provided with an optical diffraction component only in sections.

To produce a microstructured or nanostructured component, the projection exposure apparatus 1 is used as follows: first, the reflection mask 23 or the reticle and the substrate or the wafer 28 are provided. A structure on the reticle 23 is then projected onto a light-sensitive layer of the wafer 28 with the aid of the projection exposure apparatus 1. By developing the light-sensitive layer, a microstructure or nanostructure is then produced on the wafer 28 and thus the microstructured component is produced.

What is claimed is:

1. An optical illumination system, comprising:
a first EUV mirror configured to reflect EUV radiation; and
a second EUV mirror configured to reflect the EUV radiation,
wherein:
the first and second EUV mirrors are configured to guide the EUV radiation to an object field;
the first EUV mirror comprises a first diffraction grating comprising a first structure depth;
the first diffraction grating is configured to suppress extraneous light radiation at a first wavelength;
the second EUV mirror comprises a second diffraction grating comprising a second structure depth different from the first structure depth; and
the second diffraction grating is configured to suppress extraneous light radiation at a second wavelength different from the first wavelength.

2. The optical illumination system of claim 1, wherein the first diffraction grating comprises a binary diffraction grating.

3. The optical illumination system of claim 1, the first diffraction grating comprises two different diffraction structure level structures, and the second diffraction grating comprises two different diffraction structure level structures.

4. The optical illumination system of claim 1, the first diffraction grating comprises three different diffraction structure level structures, and the second diffraction grating comprises two different diffraction structure level structures.

5. The optical illumination system of claim 1, wherein the first EUV mirror comprises an EUV collector mirror, and the first diffraction grating comprises three different diffraction structure levels.

6. The optical illumination system of claim 1, wherein the first EUV mirror comprises a field facet mirror, and the first diffraction grating comprises two different diffraction structure levels.

7. The optical illumination system of claim 1, wherein the first EUV mirror comprises a pupil facet mirror, and the first diffraction grating comprises two different diffraction structure levels.

8. The optical illumination system of claim 1, wherein the first EUV mirror comprises a condenser mirror, and the first diffraction grating comprises two different diffraction structure levels.

9. The optical illumination system of claim 1, wherein a member selected from the group consisting of the first EUV mirror and the second EUV mirror comprises a facet mirror.

10. The optical illumination system of claim 1, wherein the first EUV mirror comprises a field facet mirror.

11. The optical illumination system of claim 1, wherein the first EUV mirror comprises a pupil facet mirror.

12. The optical illumination system of claim 1, wherein the first EUV mirror comprises a condenser mirror.

13. The optical illumination system of claim 1, wherein:
the first EUV mirror comprises an EUV collector mirror;
the first diffraction grating comprises three different diffraction structure levels;
the second EUV mirror comprises a field facet mirror; and
the second diffraction grating comprises two different diffraction structure levels.

14. The optical illumination system of claim 1, wherein:
the first EUV mirror comprises an EUV collector mirror;
the first diffraction grating comprises three different diffraction structure levels;
the second EUV mirror comprises a pupil facet mirror; and
the second diffraction grating comprises two different diffraction structure levels.

15. The optical illumination system of claim 1, wherein:
the first EUV mirror comprises an EUV collector mirror;
the first diffraction grating comprises three different diffraction structure levels;
the second EUV mirror comprises a condenser mirror; and
the second diffraction grating comprises two different diffraction structure levels.

16. The optical illumination system of claim 1, wherein:
the first EUV mirror comprises field facet mirror;
the first diffraction grating comprises two different diffraction structure levels;
the second EUV mirror comprises a pupil facet mirror; and
the second diffraction grating comprises two different diffraction structure levels.

17. An optical system, comprising:
an optical illumination system according to claim 1; and
a projection optical unit configured to image the object field into an image field.

18. An apparatus, comprising:
an optical illumination system according to claim 1;
a projection optical unit configured to image the object field into an image field; and
a source configured to provide the EUV radiation,
wherein the apparatus is a projection exposure apparatus.

19. A method of using a projection exposure apparatus comprising an optical illumination system and a projection optical unit, the method comprising:
using the optical illumination system to at least partially illuminate a first object in an object field of an object plane; and
using the projection optical unit to image the object onto a second object in an image field of an image plane,
wherein the optical illumination system is an optical illumination system according to claim 1.

20. The method of claim 19, wherein the first object comprises a reticle, and the second object comprises a material that is sensitive to the EUV radiation.
